(19) United States
(12) Patent Application Publication
(10) Pub. No.: US 2010/0140668 A1
(43) Pub. Date: Jun. 10, 2010

(54) SHALLOW TRENCH ISOLATION REGIONS IN IMAGE SENSORS

(76) Inventor: Eric G. Stevens, Webster, NY (US)

Correspondence Address: EASTMAN KODAK COMPANY;PATENT LEGAL STAFF, 343 STATE STREET, ROCHESTER, NY, 14650-2201, US

(21) Appl. No.: 12/616,193

(22) Filed: Nov. 11, 2009

Related U.S. Application Data
(60) Provisional application No. 61/120,519, filed on Dec. 8, 2008.

(51) Int. Cl. H01L 29/762; H01L 31/00

(52) U.S. Cl. 257/225; 438/75; 257/E31.001; 257/E29.227

(57) ABSTRACT

An image sensor includes an imaging area that includes a plurality of pixels, with each pixel including a photosensitive charge storage region formed in a substrate. A passivation implantation region contiguously surrounds the side wall and bottom surfaces of each trench in the one or more trench isolation regions. A portion of each passivation implantation region is laterally adjacent to a respective charge storage region and resides only in an isolation gap disposed between the respective charge storage region and a respective trench isolation region and does not substantially reside under the charge storage region. Each passivation implantation region is formed by implanting one or more dopants at a low energy into the side wall and bottom surfaces of each trench after annealing the image sensor and prior to filling the trenches with an insulating material.

### CROSS REFERENCE TO RELATED APPLICATION

This application claims the benefit of U.S. Provisional Patent Application 61/120,519 filed on Dec. 8, 2008, which is incorporated herein by reference.

### TECHNICAL FIELD

The present invention relates generally to image sensors for use in digital cameras and other types of image capture devices, and more particularly to shallow trench isolation regions in image sensors.

### BACKGROUND

An electronic image sensor typically captures images using an array of pixels, with each pixel including a light-sensitive photodetector for converting incident light into photo-generated charges. Shallow trench isolation (STI) regions are typically fabricated between adjacent photodetectors or pixels to isolate the photodetectors and reduce crosstalk. FIG. 1 is a simplified cross-sectional view of a portion of a pixel in accordance with the prior art. Pixel 100 includes photodetector 102 and STI region 104. In FIG. 1, photodetector 102 is configured as a pinned photodiode formed by charge storage region 106 and pinning layer 108. In general, a photodiode will collect charge generated in, or charge that makes it to, the boundary region 110 provided by the junction 112 between the p-doped charge storage region 106 and the n-doped region (e.g., well or substrate) 114.

STI region 104 is fabricated by etching a trench into region 114 and filling the trench with an insulating material. Interface 116 between STI region 104 and region 114 is typically a source for dark current and point defects. To reduce dark current and point defects, interface 116 is conventionally passivated by implanting one or more n-type dopants into the side walls and bottom of the trench. For example, one prior art passivation technique performs two passivation implantation steps after the trench is filled with the insulating layer. The first step implants a dose of phosphorus (e.g., 3×10¹² atoms per square centimeter at 250 kilo-electron volts (keV)) into the side walls and bottom of the trench, and the second step implants at a relatively high energy (e.g., 400 keV) a dose of phosphorus (e.g., 1.5×10¹³ atoms per square centimeter) into the side walls and bottom of the trench.

Unfortunately, the implanted phosphorus dopants of the isolation regions, which may or may not include STI region 104, spread laterally out into region 114 and under photodetector 102 during implantation and subsequent processing of image sensor 100. The lateral spreading of the dopants can adversely affect the collection volume of photodetector 102. FIG. 2 is a two-dimensional cross-sectional view illustrating doping contours of a photodetector between two implanted isolation regions in accordance with the prior art. The isolation regions are typically disposed on either side of photodetector 102 in a cross-section coming out of the page of FIG. 1. Contour lines 200 depict the spreading of dopants from the STI regions adjacent to charge storage region 106. As can be seen, the dopants spread laterally from the isolation regions and merge under charge storage region 106.

FIG. 3 is a graphical view of exemplary junction and depletion edges for charge storage region 106 in FIG. 1. Junction 112 is formed between the edge of charge storage region 106 and region 114. Depletion edge 300 represents the edge of depletion region 110. The spreading of the dopants in the isolation regions reduce the size of charge storage region 106 and produce a shallow depletion region 110. The reduced size of depletion region 110 also reduces the quantum efficiency of the image sensor at longer wavelengths.

### SUMMARY

An image sensor includes an imaging area that includes a plurality of pixels, with each pixel including a photosensitive charge storage region formed in a substrate. One or more shallow trench isolation (STI) regions are also formed in the substrate. The STI regions can be formed between pixels, between groups of two or more pixels, or outside the imaging area to isolate the pixels from other electronic components in the image sensor. A passivation implantation region contiguously surrounds the side wall and bottom surfaces of each trench in the one or more STI regions. A portion of each passivation implantation region is laterally adjacent to a respective charge storage region and resides in an isolation gap disposed between the respective charge storage region and a respective trench isolation region and in between the photodetectors in the other direction.

The one or more STI regions are fabricated by depositing and patterning a photoresist layer on the image sensor to form openings where one or more trenches are to be formed. The trench or trenches are formed in the substrate and the image sensor is annealed. One or more dopants are then implanted at a low energy into the side wall and bottom surfaces of each trench to form a passivation implantation region that contiguously surrounds the side wall and bottom surfaces of each trench. In image sensors that include STI regions, the passivation implantation region is also created in between photodetectors. A liner layer of oxide can be formed over the side wall and bottom surfaces of each trench either prior to, or after, implanting the dopant or dopants at a low energy into the side wall and bottom surfaces of each trench. The photoresist layer is then removed and the trench or trenches filled with an insulating material. After the trenches are filled with an insulating material, another layer of photoresist can be deposited on the image sensor and patterned to cover the sites where the photodetectors will be formed. One or more dopants can then be implanted into the STI regions, isolation regions, or FET regions in the pixels.

### ADVANTAGEOUS EFFECT OF THE INVENTION

The present invention increases the depletion region of a photodetector, thereby improving the collection efficiency of the photodetector. Therefore, the present invention also increases the quantum efficiency of the pixel and reduces pixel-to-pixel crosstalk between adjacent pixels. And finally, the present invention passivates the STI interface to reduce dark current generation.

### BRIEF DESCRIPTION OF THE DRAWINGS

Embodiments of the invention are better understood with reference to the following drawings. The elements of the drawings are not necessarily to scale relative to each other.

FIG. 1 is a simplified cross-sectional view of a portion of a pixel in accordance with the prior art;

FIG. 2 is a two-dimensional cross-sectional view illustrating doping contours of a photodetector between two implanted isolation regions in accordance with the prior art;

FIG. 3 is a graphical view of exemplary junction and depletion edges for charge storage region 110 in FIG. 1;

FIG. 4 is a simplified block diagram of an image capture device in an embodiment in accordance with the invention;

FIG. 5 is a simplified block diagram of image sensor 406 shown in FIG. 4 in an embodiment in accordance with the invention;

FIG. 6 is a cross-sectional view of a first pixel structure in an embodiment in accordance with the invention;

FIGS.7(A)-7(G) are cross-sectional views of a portion of a pixel that are used to illustrate a method for fabricating shallow trench isolation regions in an embodiment in accordance with the invention;

FIG. 8 is a two-dimensional cross-sectional view illustrating a doping contour of the first pixel structure shown in FIG. 6;

FIG. 9 is a graphical view of exemplary junction and depletion edges for charge storage region 802 in FIG. 8;

FIG. 10 is a one-dimensional doping profile of STI region 722 in FIG. 7;

FIG. 11 is a cross-sectional view of a second pixel structure in an embodiment in accordance with the invention; and

FIG. 12 is a two-dimensional cross-sectional view illustrating a doping contour of the second pixel structure shown in FIG. 11.

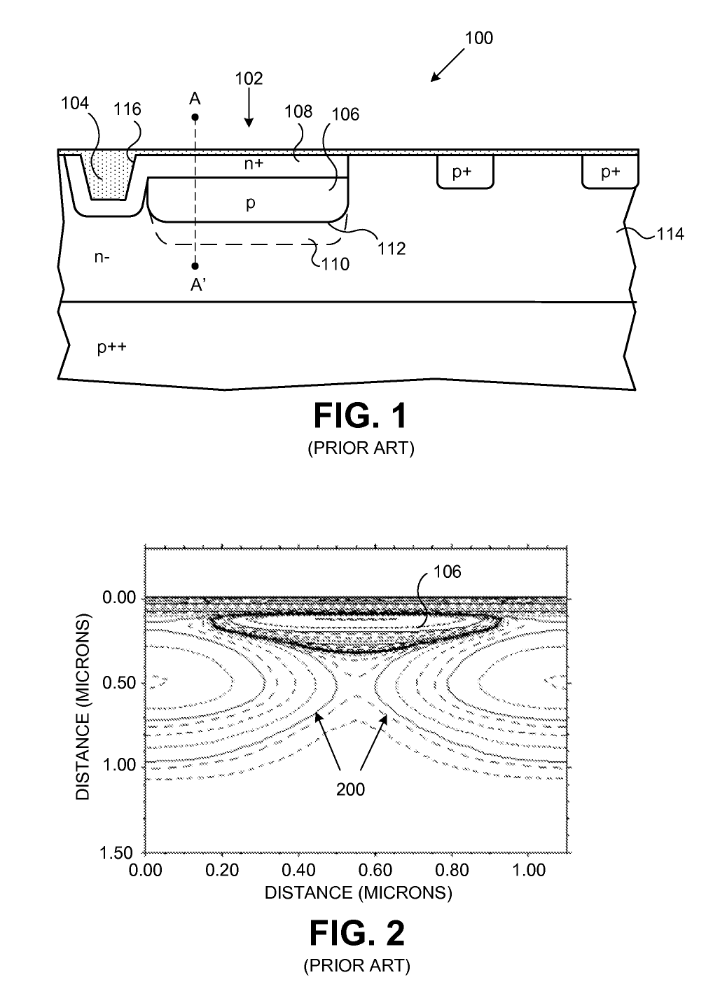

### DETAILED DESCRIPTION

Throughout the specification and claims the following terms take the meanings explicitly associated herein, unless the context clearly dictates otherwise. The meaning of “a,” “an,” and “the” includes plural reference, the meaning of “in” includes “in” and “on.” The term “connected” means either a direct electrical connection between the items connected or an indirect connection through one or more passive or active intermediary devices. The term “circuit” means either a single component or a multiplicity of components, either active or passive, that are connected together to provide a desired function. The term “signal” means at least one current, voltage, or data signal.

Additionally, directional terms such as “on”, “over”, “top”, “bottom”, are used with reference to the orientation of the Figure(s) being described. Because components of embodiments of the present invention can be positioned in a number of different orientations, the directional terminology is used for purposes of illustration only and is in no way limiting. When used in conjunction with layers of an image sensor wafer or corresponding image sensor, the directional terminology is intended to be construed broadly, and therefore should not be interpreted to preclude the presence of one or more intervening layers or other intervening image sensor features or elements. Thus, a given layer that is described herein as being formed on or formed over another layer may be separated from the latter layer by one or more additional layers.

And finally, the terms “wafer” and “substrate” are to be understood as a semiconductor-based material including, but not limited to, silicon, silicon-on-insulator (SOI) technology, doped and undoped semiconductors, epitaxial layers or well regions formed on a semiconductor substrate, and other semiconductor structures.

Referring to the drawings, like numbers indicate like parts throughout the views.

FIG. 4 is a simplified block diagram of an image capture device in an embodiment in accordance with the invention. Image capture device 400 is implemented as a digital camera in FIG. 4. Those skilled in the art will recognize that a digital camera is only one example of an image capture device that can utilize an image sensor incorporating the present invention. Other types of image capture devices, such as, for example, cell phone cameras and digital video camcorders, can be used with the present invention.

In digital camera 400, light 402 from a subject scene is input to an imaging stage 404. Imaging stage 404 can include conventional elements such as a lens, a neutral density filter, an iris and a shutter. Light 402 is focused by imaging stage 404 to form an image on image sensor 406. Image sensor 406 captures one or more images by converting the incident light into electrical signals. Digital camera 400 further includes processor 408, memory 410, display 412, and one or more additional input/output (I/O) elements 414. Although shown as separate elements in the embodiment of FIG. 4, imaging stage 404 may be integrated with image sensor 406, and possibly one or more additional elements of digital camera 400, to form a compact camera module.

Processor 408 may be implemented, for example, as a microprocessor, a central processing unit (CPU), an application-specific integrated circuit (ASIC), a digital signal processor (DSP), or other processing device, or combinations of multiple such devices. Various elements of imaging stage 404 and image sensor 406 may be controlled by timing signals or other signals supplied from processor 408.

Memory 410 may be configured as any type of memory, such as, for example, random access memory (RAM), read-only memory (ROM), Flash memory, disk-based memory, removable memory, or other types of storage elements, in any combination. A given image captured by image sensor 406 may be stored by processor 408 in memory 410 and presented on display 412. Display 412 is typically an active matrix color liquid crystal display (LCD), although other types of displays may be used. The additional 110 elements 414 may include, for example, various on-screen controls, buttons or other user interfaces, network interfaces, or memory card interfaces.

It is to be appreciated that the digital camera shown in FIG. 4 may comprise additional or alternative elements of a type known to those skilled in the art. Elements not specifically shown or described herein may be selected from those known in the art. As noted previously, the present invention may be implemented in a wide variety of image capture devices. Also, certain aspects of the embodiments described herein may be implemented at least in part in the form of software executed by one or more processing elements of an image capture device. Such software can be implemented in a straightforward manner given the teachings provided herein, as will be appreciated by those skilled in the art.

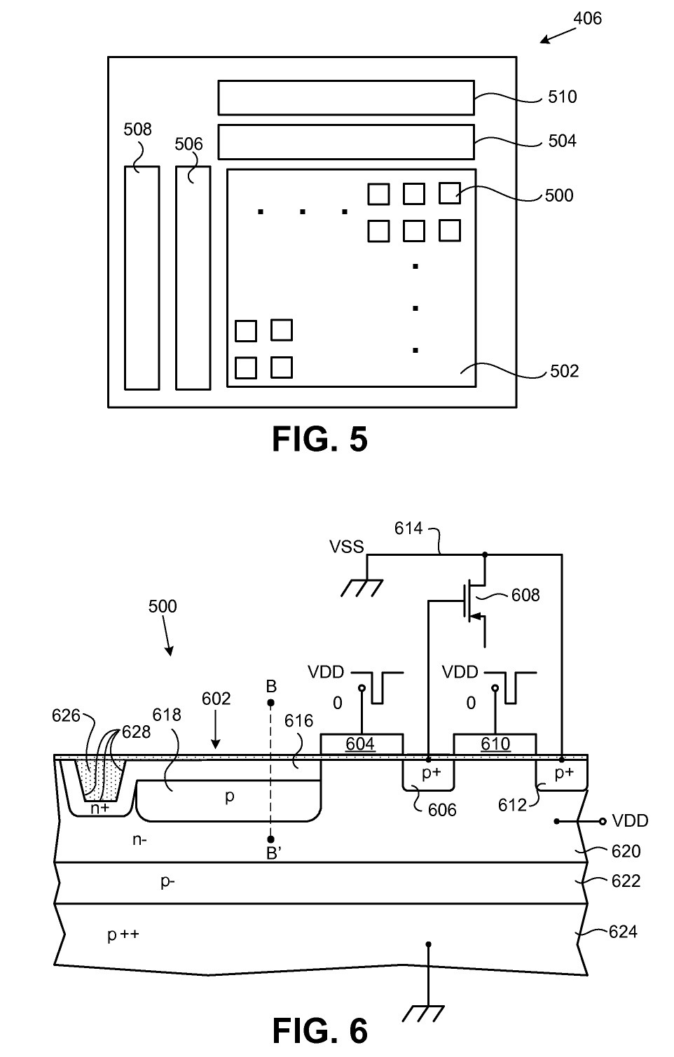

Referring now to FIG. 5, there is shown a simplified block diagram of image sensor 406 shown in FIG. 4 in an embodiment in accordance with the invention. Image sensor 406 typically includes an array of pixels 500 that form an imaging area 502. Image sensor 406 further includes column decoder 504, row decoder 506, digital logic 508, and analog or digital output circuits 510. Image sensor 406 is implemented as a back or front-illuminated Complementary Metal Oxide Semiconductor (CMOS) image sensor in an embodiment in accordance with the invention. Thus, column decoder 504, row decoder 506, digital logic 508, and analog or digital output circuits 510 are implemented as standard CMOS electronic circuits that are electrically connected to imaging area 502.

Functionality associated with the sampling and readout of imaging area 502 and the processing of corresponding image data may be implemented at least in part in the form of software that is stored in memory 410 and executed by processor 408 (see FIG. 4). Portions of the sampling and readout circuitry may be arranged external to image sensor 406, or formed integrally with imaging area 502, for example, on a common integrated circuit with photodetectors and other elements of the imaging area. Those skilled in the art will recognize that other peripheral circuitry configurations or architectures can be implemented in other embodiments in accordance with the invention.

FIG. 6 is a cross-sectional view of a first pixel structure in an embodiment in accordance with the invention. Pixel 500 is implemented as a p-type metal-oxide-semiconductor (pMOS) pixel in the embodiment of FIG. 6. Other embodiments in accordance with the invention can implement pixel 500 as an n-type metal-oxide-semiconductor (nMOS) pixel with appropriate reverse conductivity types as recognized by one skilled in the art.

Pixel 500 includes photodetector 602 that collects and stores charge that is generated in response to light striking photodetector 602. Transfer gate 604 is used to transfer the integrated charge in photodetector 602 to charge-to-voltage converter 606. Converter 606 converts the charge into a voltage signal. Source-follower transistor 608 buffers the voltage signal stored in charge-to-voltage converter 606. Reset transistor 606, 610, 612 is used to reset charge-to-voltage converter 606 to a known potential prior to pixel readout. And power supply voltage (VSS) 614 is used to supply power to source follower transistor 608 and drain off signal charge from charge-to-voltage converter 606 during a reset operation.

Photodetector 602 is implemented as a pinned photodiode consisting of n+ pinning layer 616 and p-type charge storage region 618 formed within n-type well 620. Well 620 is formed within p-type epitaxial layer 622. Epitaxial layer 622 is disposed on p-type substrate 624.

Shallow trench isolation (STI) regions 626 are formed between the pixels, or between groups of two or more pixels, to isolate the pixels or groups of pixels from one another. Interface 628 resides between STI region 626 and pinning layer 616 and well 620 in the embodiment shown in FIG. 6. In another embodiment in accordance with the invention, where photodetector 602 is configured as an unpinned photodetector, interface 628 resides between STI region 626 and well 620. And finally, in yet another embodiment in accordance with the invention, interface 628 is created between STI region 626 and epitaxial layer 622 or some other type of substrate.

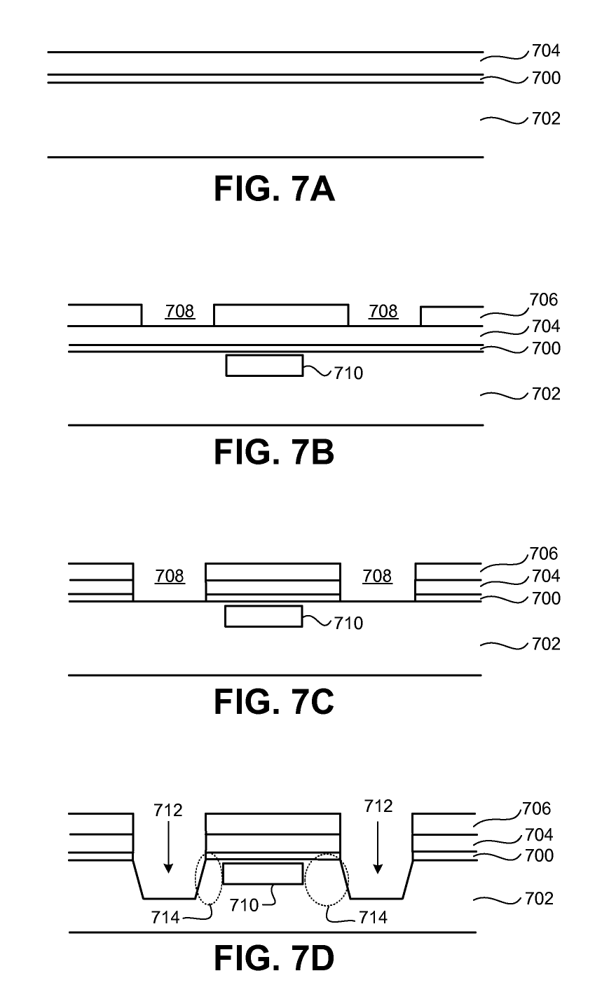

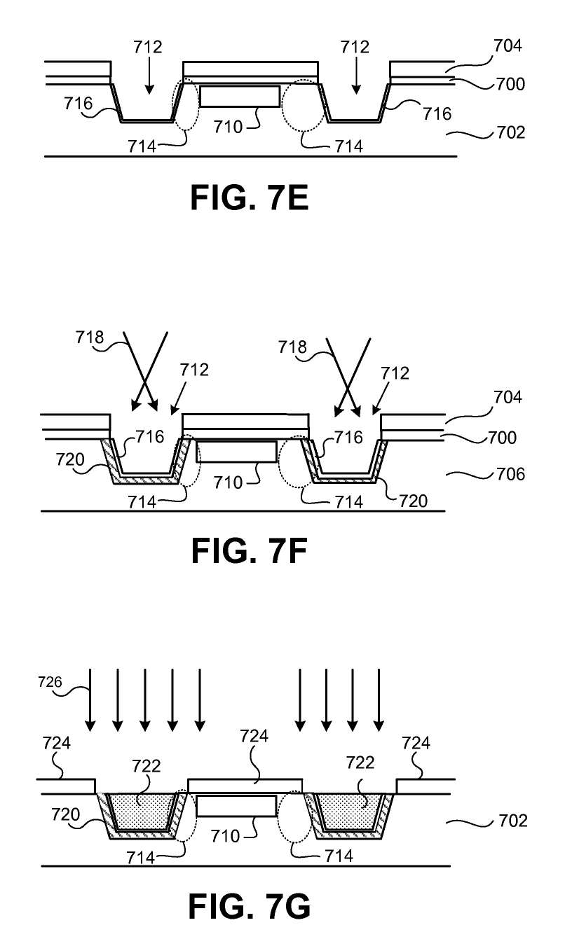

Referring now to FIGS. 7(A)-7(G), there are shown cross-sectional views of a portion of a pixel that are used to illustrate a method for fabricating shallow trench isolation regions in an embodiment in accordance with the invention. FIG. 7(A) shows the portion of the pixel after a number of initial CMOS fabrication steps have been completed. The pixel at this stage includes an insulating layer 700 formed over substrate 702. Layer 704 is formed over insulating layer 700. Insulating layer 700 and layer 704 are configured as layers of silicon dioxide and silicon nitride, respectively, in an embodiment in accordance with the invention.

A photoresist layer 706 is then deposited and patterned over the image sensor to form openings 708 where STI regions are to be formed (see FIG. 7(B)). Box 710 represents a site where a photodetector will eventually be formed. Next, as shown in FIG. 7(C), layers 704 and 700 are etched to match the pattern in photoresist 706. Trenches 712 are then formed by etching the exposed substrate 702 in openings 708 (see FIG. 7(D)). Trenches 712 are etched such that isolation gaps 714 (indicated by dashed circles) are created between trenches 712 and site 710. Isolation gaps 714 are immediately adjacent trenches 712 and do not extend under the charge storage region of the yet to be formed photodetector. Next, photoresist 706 is removed, as shown in FIG. 7(E). A liner layer 716 of oxide is then thermally grown on the side wall and bottom surfaces of trenches 712 (see FIG. 7(F)) and an anneal process performed on the image sensor. The anneal process reduces any detrimental effects caused by etching epitaxial layer 702 to form trenches 712 and by the formation of the insulating oxide layer 716. The anneal smoothes out the surfaces of the side walls and bottoms of trenches 712, relieves stress, and reduces dangling bonds and surface states along the side walls and bottoms of trenches 712.

A low energy passivation implantation at different angles (illustrated by the arrows 718) is then performed to implant dopants into the side wall and bottom surfaces of trenches 712. Performing the low energy passivation implantation after the liner layer 716 is grown can minimize lateral spreading of the dopants. In one embodiment in accordance with the invention, a dose of arsenic (1.5×10¹³ atoms per square centimeter) is implanted at 40 keV into the side wall and bottom surfaces of trenches 712. This low-energy implantation forms passivation implantation regions 720 along the side walls of trenches 712 in isolation gaps 714 and along the bottoms of trenches 712 in substrate 702.

Next, layer 704 and insulating layer 700 are removed, as shown in FIG. 7(G). An insulating layer, such as a silicon dioxide layer, is deposited over the image sensor and selectively removed so that trenches 712 are filled with insulating material and form STI regions 722. Although not shown in FIG. 7, an oxide is typically grown before the next processes are performed.

Photoresist 724 is then deposited and patterned to cover site 710 where a photodetector will be subsequently formed, as well as other areas that will not be included in a second passivation implantation. The second passivation implantation is performed (illustrated by the arrows 726) to implant dopants around and into STI regions 722. By way of example only, the second passivation implantation is performed in two steps in an embodiment in accordance with the invention, with the first step implanting a dose of arsenic (1.2×10¹³ atoms per square centimeter) at 130 keV, and the second step implanting a dose of phosphorus (5×10¹² atoms per square centimeter) at 140 keV.

Photoresist 724 is then removed and production of the image sensor is now completed using traditional fabrication processes well known in the art. For example, the photodetectors will be formed by implanting dopants into substrate 702. Since these fabrication processes are well known, the steps will not described in detail herein.

Although the embodiment of FIG. 7 is described as implanting particular doses of arsenic and phosphorus into the side wall and bottom surfaces of the trenches for a pMOS pixel, embodiments in accordance with the invention are not limited to these two particular dopants or doses. One or more different types of n-type dopants or different dosage amounts can be implanted into the side walls and bottom surfaces of the trenches in other embodiments in accordance with the invention. Alternatively, for an nMOS pixel, appropriate conductivity types are reversed as will be recognized by one skilled in the art. Thus, when the charge storage regions are doped with an n-type dopant, one or more p-type dopants can be implanted into the side wall and bottom surfaces of the trenches.

Moreover, other embodiments in accordance with the invention can include additional or alternative fabrication steps. And some of the fabrication steps shown in FIG. 7 can be performed in a different order. For example, the low-energy implantation can be performed before the liner layer 716 of oxide is formed on the side walls and bottoms of the trenches 712.

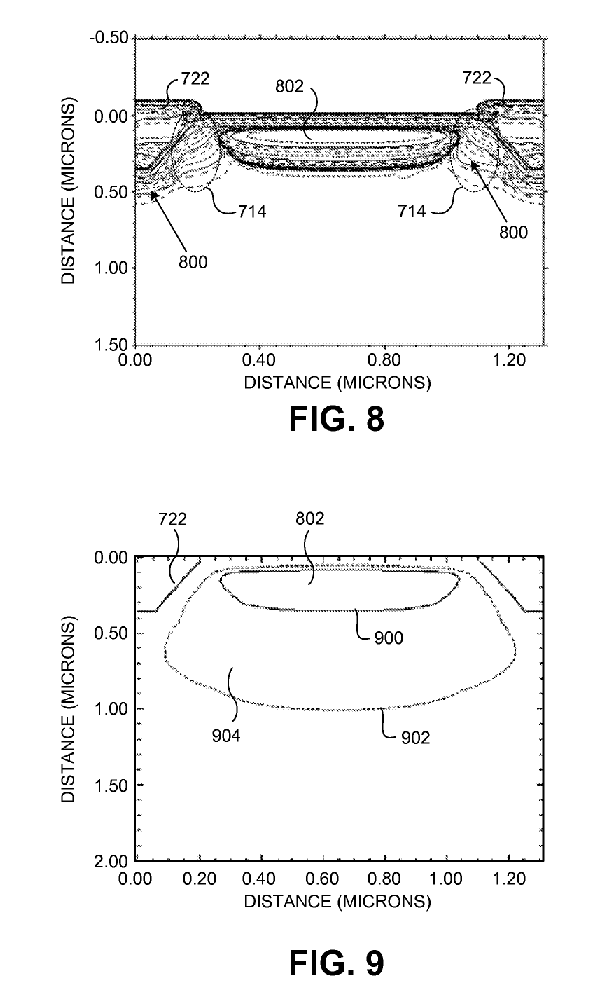

FIG. 8 is a two-dimensional cross-sectional view illustrating a doping contour of the first pixel structure shown in FIG. 6. Contour lines 800 depict lines of constant doping density from passivation implantation regions 720. As can be seen, the dopants surround the sides of STI regions 722 and isolation gaps 714. The dopants also spread into substrate 702 or surround the bottom of STI regions 722. The dopants do not, however, significantly diffuse under charge storage region 802. This minimal encroachment by the dopants into the depletion region of a photodetector opens up the depletion region and increases collection volume of the photodetector.

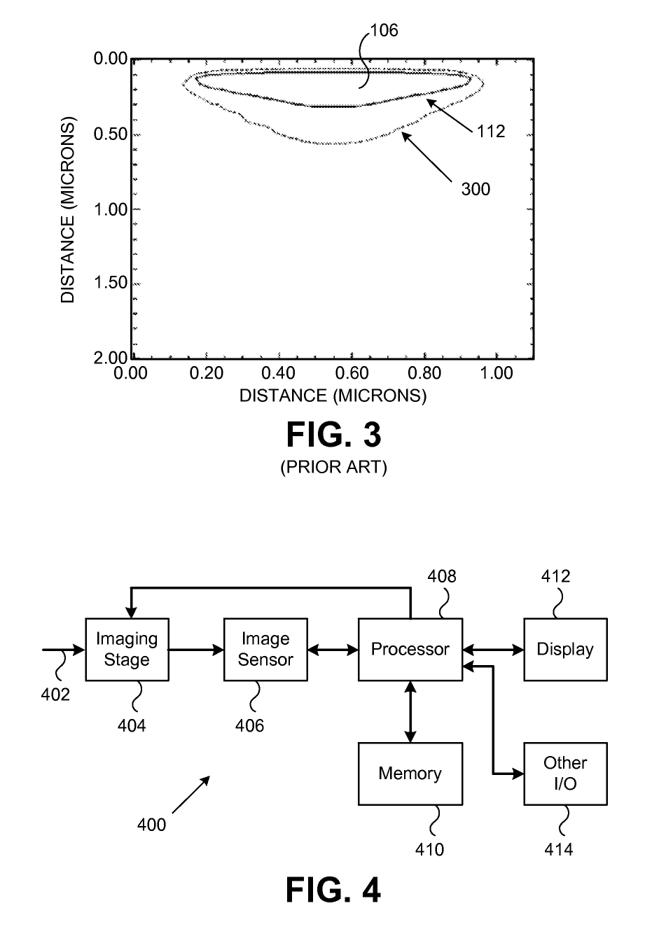

FIG. 9 is a graphical view of exemplary junction and depletion edges for charge storage region 802 in FIG. 8. Junction 900 is formed between the edge of charge storage region 802 and a substrate. Depletion edge 902 represents the boundary of depletion region 904. Both charge storage region 802 and depletion region 904 are larger in size than the prior art charge storage region 106 and depletion region 300 shown in FIG. 3. As discussed earlier, the larger charge storage region 802 and depletion region 904 increase the collection volume of the photodetector.

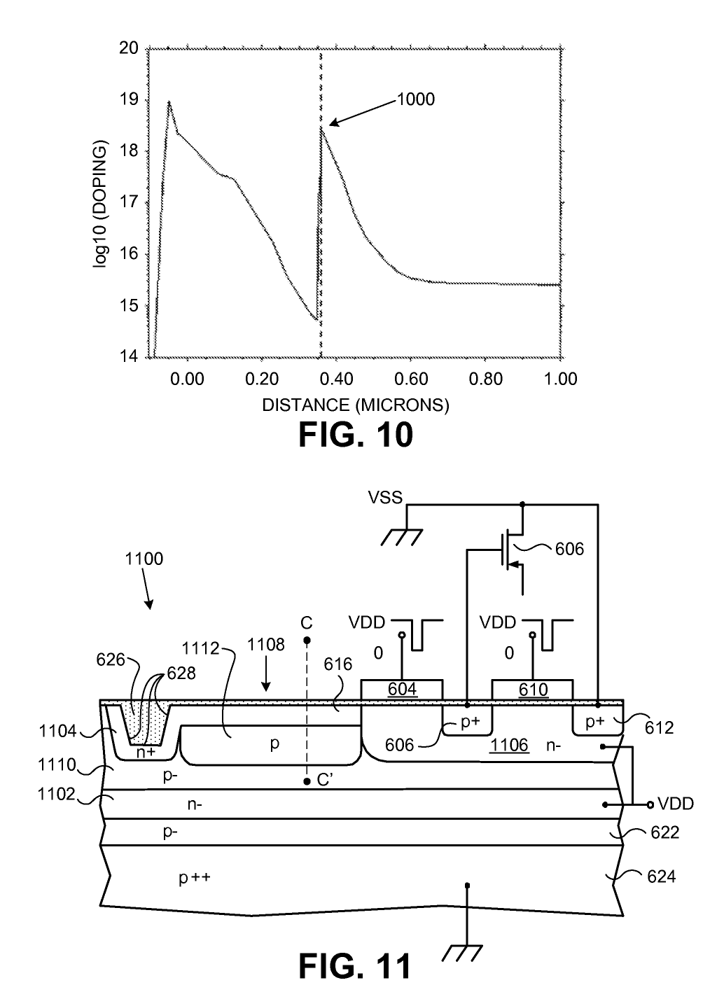

Moreover, the interface between STI regions 722 and substrate 702 are passivated effectively, thereby reducing dark current. FIG. 10 is a one-dimensional doping density plot of STI region 722 in FIG. 7. The plot is down through the center of the trench. As can be seen, the doping density at the bottom of STI regions 722 is approximately 2×10¹⁸ cm⁻³ to 3×10¹⁸ cm⁻³ (see point 1000). The doping concentration along the trench side wall is at this same order of magnitude.

Referring now to FIG. 11, there is shown a cross-sectional view of a second pixel structure in an embodiment in accordance with the invention. Pixel 1100 includes transfer gate 604, charge-to-voltage converter 606, source follower transistor 608, reset transistor 606, 610, 612, pinning layer 616, epitaxial layer 622, substrate 624, and STI region 626 described in conjunction with FIG. 6. Buried n-type layer 1102 is formed within a portion of epitaxial layer 622. N-type wells 1104, 1106 are formed within another portion of epitaxial layer 622. Well 1106 is contained within pixel 1100 and is disposed laterally adjacent to and abutting photodetector 1108.

Region 1110 of epitaxial layer 622 is positioned between buried layer 1102, photodetector 1108, and wells 1104, 1106. The doping of the region 1110 is substantially the same as the doping of epitaxial layer 622 in an embodiment in accordance with the invention. Region 1110 effectively produces an “extension” of p-type charge storage region 1112 in photodetector 1108. This results in a deeper depletion depth and a deeper junction depth for photodetector 1108.

Additionally, isolation region 626, when fabricated pursuant to the method shown in FIG. 7, has an interface 628 that is effectively passivated. There is minimal encroachment by the passivation implantation region dopants into the depletion region of photodetector 1108. In an alternate embodiment in accordance with the invention, wells 1104, 1106 abut and make direct contact with buried layer 1102. U.S. patent application Ser. No. 12/054,505, filed on Mar. 25, 2008 and entitled “A Pixel Structure With A Photodetector Having An Extended Depletion Depth,” incorporated by reference herein, describes in more detail the pixel structure of FIG.11 and an alternate pixel structure where wells 1104, 1106 abut buried well 1102.

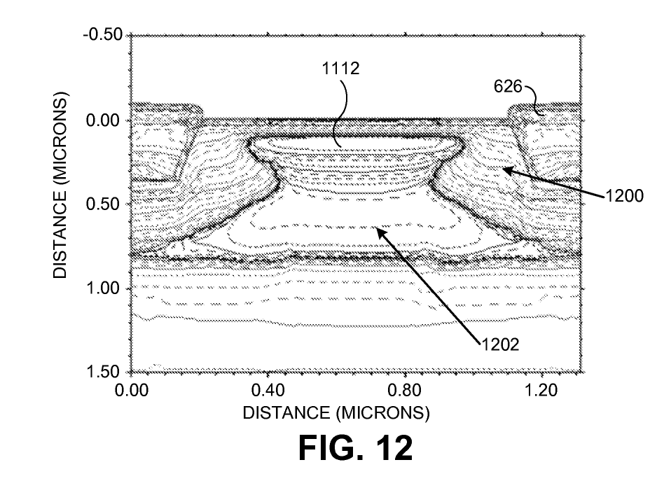

FIG. 12 is a two-dimensional cross-sectional view illustrating a doping contour of the alternate second pixel structure described in conjunction with FIG. 11. In this embodiment, wells 1104, 1106 abut and make direct contact with buried layer 1102. Contour lines 1200 depict the spreading of dopants from the passivation implantation region surrounding STI region 626. As can be seen, the dopants surround the sides and bottom of STI region 626. The dopants do not, however, significantly spread under charge storage region 1112. Additionally, region 1110 (not shown in FIG. 12) effectively produces an extension 1202 of charge storage region 1112 in photodetector 1108 (1108 and 1112 not shown in FIG. 12). This extension results in a deeper depletion depth and a deeper junction depth for photodetector 1108.

The invention has been described with reference to particular embodiments in accordance with the invention. However, it will be appreciated that variations and modifications can be effected by a person of ordinary skill in the art without departing from the scope of the invention. By way of examples only, an image sensor can be implemented as a CMOS image sensor or a charge-coupled device (CCD) image sensor. A bulk wafer overlying the substrate can be used instead of substrate 624 and epitaxial layer 622. Photodetector 602 (FIG. 6) or photodetector 1108 (FIG. 11) can be implemented using alternate structures or conductivity types in other embodiments in accordance with the invention. Photodetectors 602, 1108 can be implemented as an unpinned p-type diode formed in an n-well in a p-type substrate in another embodiment in accordance with the invention. In other embodiments in accordance with the invention, photodetector 602, 1108 can include a pinned or unpinned n-type diode formed within a p-well in an n-type substrate. And finally, although a simple non-shared pixel structure is shown in FIG. 6 and FIG. 11, a shared architecture is used in another embodiment in accordance with the invention. One example of a shared architecture is disclosed in U.S. Pat. No. 6,107,655.

Additionally, even though specific embodiments of the invention have been described herein, it should be noted that the application is not limited to these embodiments. In particular, any features described with respect to one embodiment may also be used in other embodiments, where compatible. And the features of the different embodiments may be exchanged, where compatible.

### PARTS LIST

100 pixel
102 photodetector
104 shallow trench isolation (STI) region
106 charge storage region
108 pinning layer
110 depletion region
112 junction
114 substrate
116 interface
200 contour lines
300 junction of charge storage region
302 edge of depletion region
400 image capture device
402 light
404 imaging stage
406 image sensor
408 processor
410 memory
412 display
414 other input/output devices
500 pixel
502 imaging area
504 column decoder
506 row decoder
508 digital logic
510 analog or digital output circuits
602 photodetector
604 transfer gate
606 charge-to-voltage converter
608 source follower transistor
610 gate of reset transistor
612 source/drain of reset transistor
614 power supply voltage
616 pinning layer
618 charge storage region
620 well
622 epitaxial layer
624 substrate
626 STI region
628 interface
700 insulating layer
702 substrate
704 layer
706 photoresist
708 openings
710 site of to be formed photodetector
712 trench
714 isolation gap
716 liner layer
718 arrows representing dopant implantation
720 passivation implantation regions
722 STI region
724 photoresist
726 arrows representing dopant implantation
800 contour lines
802 charge storage region
900 junction of charge storage region
902 edge of depletion region
904 depletion region
1000 dopant density at interface
1100 pixel
1102 buried layer
1104 well
1106 well
1108 photodetector
1110 region
1112 charge storage region
1200 contour lines
1202 extension of charge storage region

What is claimed is:

1. An image sensor comprising:
an imaging area that includes a plurality of pixels each including a charge storage region formed in a substrate;
one or more trench isolation regions formed in the substrate, wherein each trench isolation region includes a trench having side wall surfaces and a bottom surface; and
a passivation implantation region contiguously surrounding the side wall and bottom surfaces of each trench isolation region, wherein a portion of each passivation implantation region that is laterally adjacent to a respective charge storage region resides only in an isolation gap region disposed between the respective charge storage region and a respective trench isolation region and does not substantially reside under the charge storage region.

2. The image sensor of claim 1, further comprising one or more electronic components disposed in each pixel.

3. The image sensor of claim 1, further comprising one or more electronic components disposed outside of the imaging area and electrically connected to the imaging area.

4. The image sensor of claim 1, further comprising a pinning layer formed over each charge storage region to form a pinned photodiode.

5. An image capture device comprising:
an image sensor comprising:
an imaging area that includes a plurality of pixels each including a charge storage region formed in a substrate;
one or more trench isolation regions formed in the substrate, wherein each trench isolation region includes a trench having side wall surfaces and a bottom surface; and
a passivation implantation region contiguously surrounding the side wall and bottom surfaces of each trench isolation region, wherein a portion of each passivation implantation region that is laterally adjacent to a respective charge storage region resides only in an isolation gap region disposed between the respective charge storage region and a respective trench isolation region and does not substantially reside under the charge storage region.

6. The image capture device of claim 5, wherein the image sensor further comprises one or more electronic components disposed in each pixel.

7. The image capture device of claim 5, further comprising one or more electronic components disposed outside of the imaging area and electrically connected to the imaging area.

8. The image capture device of claim 5, further comprising a pinning layer formed over each charge storage region to form a pinned photodiode.

9. A method of fabricating an image sensor having a plurality of pixels, with each pixel including a charge storage region formed in a substrate, the method comprising:
forming one or more trench isolation regions in the substrate, wherein each trench isolation region includes a trench having side wall surfaces and a bottom surface;
annealing the image sensor;
implanting at low energy one or more dopants into the side wall and bottom surfaces of each trench isolation region to form a passivation implantation region that contiguously surrounds the side wall and bottom surfaces of each trench isolation region, wherein a portion of each passivation implantation region that is laterally adjacent to a respective charge storage region resides only in an isolation gap region disposed between the respective charge storage region and a respective trench isolation region and does not substantially reside under the charge storage region; and
filling the one or more trench isolation regions with an insulating material.

10. The method of claim 9, further comprising forming an oxide layer over the sidewalls and bottom of the trench isolation regions prior to implanting at low energy one or more dopants into the side wall and bottom surfaces of each trench isolation region.

11. The method of claim 9, further comprising forming an oxide layer over the sidewalls and bottom of the trench isolation regions after implanting at low energy one or more dopants into the side wall and bottom surfaces of each trench isolation region.

12. The method of claim 9, further comprising:
prior to forming one or more trench isolation regions in the substrate, forming a first photoresist layer over the image sensor; and
patterning the first photoresist layer to create openings in the first photoresist layer where the one or more trench isolation regions are to be formed.

13. The method of claim 12, further comprising removing the first photoresist layer prior to filling the one or more trench isolation regions with an insulating material.

14. The method of claim 12, wherein implanting at low energy one or more dopants into the side wall and bottom surfaces of each trench isolation region comprises implanting at low energy one or more dopants through the openings in the first photoresist layer and into the side wall and bottom surfaces of each trench isolation region to form a passivation implantation region that contiguously surrounds the side wall and bottom surfaces of each trench isolation region.

15. The method of claim 13, further comprising:
forming a second photoresist layer over the image sensor, and
patterning the second photoresist layer to cover sites where the charge storage regions are to be formed.

16. The method of claim 15, further comprising implanting one or more dopants into the trench isolation regions after the one or more trench isolation regions are filled with the insulating material.
